(19) United States
(12) Patent Application Publication
(10) Pub. No.: US 2015/0324499 A1
(43) Pub. Date: Nov. 12, 2015

(54) Hash Fast Marching Method for Simulation of Surface Evolution in Photoresist Etching Process

(71) Applicant: SOUTHEAST UNIVERSITY, Jiangsu (CN)

(72) Inventors: Zaifa Zhou, Jiangsu (CN); Lili Shi, Jiangsu (CN)

(21) Appl. No.: 14/649,661

(22) PCT Filed: Oct. 16, 2013
(86) PCT No.: PCT/CN2013/085283

§ 371 Date: Jun. 4, 2015

(30) Foreign Application Priority Data
Dec. 13, 2012 (CN) 201210538668.2

(51) Int. Cl. G06F 17/50; G06F 17/10; G03F 7/20

(52) U.S. Cl. CPC G06F 17/5009; G03F 7/20; G06F 17/10

(57) ABSTRACT

Disclosed is a hash fast marching method for simulation of surface evolution in a photoresist etching process, including: dividing a substrate into grids and determining an etching speed matrix, initializing a grid point time value, building a hash table and a minimum heap, marching forward and performing an update, and repeating the foregoing steps until a time value of a minimum root node is not smaller than a preset photoresist etching (photoresist development) time. In the invention method, calculation is performed only for grid points in a narrow band (NarrowBand) around the established surface, and this narrow band only has a width of one grid point, so that higher iteration efficiency is achieved.

### CROSS-REFERENCE

This application is a US National Stage of International Application No. PCT/CN2013/085283 filed Oct. 16, 2013, which claims the benefit of CN 201210538668.2 filed Dec. 13, 2012, each herein fully incorporated by reference.

### FIELD OF THE INVENTION

The present invention relates to the technical field of simulation of thick resist photolithography processes, and provides a hash fast marching method for simulation of surface evolution in a photoresist etching process.

### DESCRIPTION OF RELATED ART

In conventional research methods for micro-electro-mechanical systems (MEMS) manufacturing, generally, a large number of tests are performed in order to obtain the optimal process condition for the size and structure of a particular device. The manufacturing tests require high investment costs. Because the final appearance is sensitive to every condition in the manufacturing process, a large number of tests need to be performed for combinations of process conditions, and the testing results need to be compared with each other so as to obtain the optimal process condition. In addition, this does not help the accurate understanding of the principle of the manufacturing process. Using a computer to simulate the photolithography process can shorten the device design cycle and reduce the design costs.

The photoresist etching process is an important step in a thick resist photolithography process. Currently, methods for simulating the photoresist etching process mainly include a cellular automaton method and a fast marching method. The cellular automaton method has a high speed and good stability; however, when applied to simulation of the thick resist photolithography, because the simulation process involves a large number of computations, the speed of the cellular automaton method cannot meet actual requirements. The fast marching method has a higher computing speed, and can better process various surface evolution situations. However, the existing fast marching method still has a problem that too many storage units are required in the simulation process. More storage units required in the simulation process indicates higher requirements on the memory of the computer. If the memory of the computer is limited, the grid array that can be used in the simulation process is small, and the precision of the simulation result is inevitably low. Therefore, the existing fast marching method cannot meet the actual requirements of high-precision simulation.

### SUMMARY OF THE INVENTION

An objective of the present invention is to provide a hash fast marching method for simulation of surface evolution in a photoresist etching process, so as to solve the problem that the existing methods for simulation of surface evolution in the photoresist etching process cannot meet the requirements on the simulation speed and the storage units at the same time. The current requirements of the fast marching method on storage space are lowered while ensuring the simulation precision and without lowering the speed, which is of practical significance to achieve a quick and precise simulation of the thick resist photolithography process.

The present invention takes into consideration a three-dimensional curved surface, which separates one area from another area. Assume that the curved surface moves along its outer normal direction at a known speed ν, and it is known that ν>0, that is, ν is always a positive value; in this case, the curved surface always extends outwards, that is, negative growth will not occur under any circumstances. Because the speed function is always positive, the time of arrival at a fixed grid point is single-valued, and the time value changes along “one path”, that is, from a smaller time value to a larger time value. Therefore, for grid points that have been crossed, the corresponding time values remain unchanged and therefore do not need to be calculated again, and only an outward equation needs to be constructed. For subsequent grid points, the calculation of their time values does not affect the time values of the grid points that have been crossed previously. In the fast marching simulation method, calculation is performed only for grid points in a narrow band (NarrowBand) around the established surface, and this narrow band only has a width of one grid point, so that higher iteration efficiency is achieved.

a. According to the characteristic that calculation is performed only for narrow band (NarrowBand) grid points in a fast marching simulation method, a hash table is introduced, and a dedicated data structure is designed to store data information of NarrowBand grid points.

b. According to the unidirectional advancement of the etching surface, an etching speed array is reused to store a time value of a grid point that has been crossed, and a sign of a reused value is used to distinguish states of different grid points.

c. A queue for recycling a hash table node is established so that space applied for in the fast marching simulation method can be directly extracted from the queue, thereby avoiding the process in which the system frequently applies for space to be released, and reducing the time required for simulation.

A fast marching simulation method that satisfies the above three conditions is considered to be a hash fast marching method for simulation of surface evolution in a photoresist etching process.

To achieve the above objective, the following technical solution may be used in the present invention:

A hash fast marching method for simulation of surface evolution in a photoresist etching process includes the following steps:

step 1: dividing a substrate into a grid array consisting of small squares, using a two-dimensional array to represent the grid array, determining a total photoresist etching time, calculating etching speeds of different photoresist and substrate material grid points, and obtaining a two-dimensional etching speed matrix;
step 2: defining grid points on a boundary of a curve as NarrowBand, grid points inside the curve as Alive, and grid points outside the curve as FarAway, and initializing time values of all the grid points according to the etching speeds of the different grid points;
step 3: building a NarrowBand hash table according to coordinate values of the NarrowBand grid points by using a periodic boundary condition, building a minimum heap according to a time value of each hash table node, and assigning values to keynum, time, and heapnum of each hash table node, four neighboring node pointers, and a next pointer;
step 4: extracting a top root node from the minimum heap, deleting the node from the NarrowBand hash table, putting the node into a recycling queue, setting all pointers that point to the node to Null, and setting a value of a speed array at the same position to the opposite of the minimum value; looking up the NarrowBand hash table for a non-Alive neighboring node of the node with the minimum time value, and if a non-Alive neighboring node of the node with the minimum time value can be found, recalculating the time value of the node, and updating the position of the node in the minimum heap, or if a non-Alive neighboring node of the node with the minimum time value cannot be found, inserting the neighboring node into the NarrowBand hash table according to a hash value; and at the same time inserting the node into the minimum heap according to the time value that is calculated first time, comprising completing internal re-sorting of the minimum heap; and
step 5: repeating the step 4 until the time value reaches a preset photoresist etching time, and at this time, obtaining a curve consisting of NarrowBand grid points, that is, a surface profile of the photoresist in the preset etching time, according to the coordinate values of the NarrowBand grid points that are stored the hash table nodes.

According to one aspect of the hash fast marching method for simulation of surface evolution in a photoresist etching process of the present invention, the time value of a child node at each level of the minimum heap is greater than the time value of a parent node, and the time values of two nodes at a same level are arbitrary.

The present invention lowers the memory space requirements of conventional methods for simulation of surface evolution in a two-dimensional photoresist etching process, and has the advantages of high precision, high speed, and occupying small memory space, and can quickly and accurately simulate a two-dimensional photolithography process. An SU-8 resist photolithography process is successfully simulated on a Core2/2 GHz computer. For an M×M grid array, the hash fast marching simulation method requires a memory space of 4.8M²+32O(M) bytes; while the conventional fast marching simulation method requires a memory space of 3×4M²+0.1×4M²=12.4M² bytes. Therefore, when M takes a large value, the present invention saves a storage space of (12.4M²-4.8M²-32O(M))/12.4M²=61.3% compared to the conventional fast marching simulation method. Compared to the improved fast marching method previously proposed by the inventor, the present invention can further reduce the required memory space by about 30%, and increase the speed by about 12%, which is of practical significance to achieve high precision simulation of the thick resist photolithography process.

### BRIEF DESCRIPTION OF THE DRAWINGS

The present invention is further described in detail with reference to the accompanying drawings and embodiments. In the drawings:

FIG. 1a is a schematic view of a narrow band in a two-dimensional fast marching method, where A represents Alive, that is, grid points inside the curve, N represents NarrowBand, that is, grid points on a boundary of the curve, and F represents FarAway, that is, grid points outside the curve; FIG. 1b is a schematic enlarged view of part 101 in FIG. 1a.

FIG. 2 is a basic flowchart of a hash fast marching method.

FIG. 3a is a schematic view of hash table initialization of a hash fast marching method, where A represents Alive, that is, grid points inside the curve, N represents NarrowBand, that is, grid points on a boundary of the curve, and F represents FarAway, that is, grid points outside the curve.

FIG. 3b is a NarrowBand hash table built according to hash values obtained by performing a remainder operation on coordinate values of NarrowBand grid points.

FIG. 4a and FIG. 4b are views illustrating data structures of NarrowBand hash table nodes, where FIG. 4a illustrates the data format of a node, in which k represents keynum and is used for storing coordinate values of NarrowBand grid point, h represents heapnum and is used for storing the position of the node in the minimum heap, t represents time that refers to the time at which the curve reaches the node (that is, the NarrowBand grid point corresponding to the node), *l, *r, *u, and *d* respectively represent *left, *right, *up, and *down pointers and are used for storing pointers that point to left, right, upper and lower neighboring nodes in space, and if a neighboring node already exists in the NarrowBand hash table, point to the node, or if a neighboring node does not exist, point to Null; and FIG. 4b is a schematic view illustrating the relationship of positions between four spatial pointers in the NarrowBand hash table node, *l, *r, *u, and *d* respectively represents *left, *right, *up, and *down points and are used for storing pointers that point to left, right, upper and lower neighboring nodes in space, and N represents Null, indicating that no node in the NarrowBand hash table satisfies the spatial relationship.

FIG. 5 is a schematic structural view of a minimum heap built in a hash fast marching method. The minimum heap means that the time value of the root node (parent node at the highest level) is the minimum value among the time values of all nodes in the heap. For example, the time value of a parent node Root1 in the figure is T=0.6 (the time value at which the grid point (2, 8) is reached), the time values of two child nodes Root2 and Root3 of the parent node Root1 are respectively T=1.3 (the time value at which the grid point (3, 5) is reached) and T=1.6 (the time value at which the grid point (6, 8) is reached). In the hash fast marching method, after the time value of a node in the NarrowBand is updated in the simulation process, the position of the node in the minimum heap also needs to be updated.

FIG. 6 is a schematic view of updating a time value in a hash fast marching method. Symbols in each node respectively represent the coordinate value and the time value, the node (i, j) to be updated is located in the center, and assume that the time value of the node after being updated is T′, and the time values at which the four neighboring nodes are reached as respectively P, S, W, and Z.

FIG. 7a and FIG. 7b are schematic views of a process of simulating surface evolution in a photoresist etching process by using a hash fast marching method, where the etching surface consists of NarrowBand grid points (corresponding to corresponding NarrowBand hash table nodes) with mesh patterns; FIG. 7a is a schematic view of the etching surface at an initial moment; FIG. 7b is a schematic view of the etching surface after an etching time.

FIG. 8 illustrates a simulation result of an SU-8 resist oblique incident photolithography process that is obtained by using a hash fast marching method.

### DETAILED DESCRIPTION OF THE INVENTION

The present invention is further described in detail with reference to the accompanying drawings and specific embodiments. It will be appreciated that these embodiments are merely used for describing the present invention rather than limiting the scope of the present invention. Any equivalent modification made by those skilled in the art after reading the present invention shall fall within the scope defined by the claims of the present application.

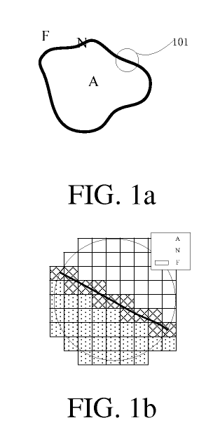

FIG. 1a is a schematic view of a narrow band in a fast marching method. FIG. 1a illustrates a known two-dimensional closed curve, where a black narrow band is the contour of the curve. FIG. 1b is an enlarged view of part 101 in FIG. 1a, where grid lattices with dotted patterns are grid points that have been crossed (represented by A), that is, grid points inside the curve, white grid lattices are grid points that have not been reached, that is, grid points outside the curve (represented by F), and grid lattices with meshed patterns are narrow band grid points, that is, grid points on a boundary of the curve (represented by N). In the simulation process using the fast marching method, calculation is performed only for grid points in a narrow band around the established surface, and this narrow band only has a width of one grid point. For the two-dimensional simulation of the etching process, a two-dimensional grid is defined in space according to a Cartesian coordinate system, where h′ represents a spatial step length, T(i, j) represents the time value at which the curve reaches the grid point (i, j). According to ν_{i,j}·dT=dS=\sqrt{dx²+dy²}, equation (1) is obtained:

νi,j|∇|=1 (1)

where dS is the distance in the normal direction, ν_{i,j} represents the speed of the grid point (i, j) in the normal direction in the moving process; spatial derivatives of equation (1) are approximated by using an upwind scheme to obtain

$${{V}_{ij} [ \begin{matrix}{max ( max ( {D}_{i , j}^{- x} T , 0 ) , - min ( {D}_{i , j}^{+ x} T , 0 ) )}^{2} \\ + {max ( max ( {D}_{i , j}^{- y} T , 0 ) , - min ( {D}_{i , j}^{+ y} T , 0 ) )}^{2}\end{matrix} ]}^{1 \text{/} 2} = 1 \qquad ( 2 )$$

where max and min respectively represent solving the maximum value and the minimum value, and

$${D}_{i , j}^{+ x} T = \frac{T ( i , j + 1 ) - T ( i , j )}{{h}^{′}}$$

$${D}_{i , j}^{- x} T = \frac{T ( i , j ) - T ( i , j - 1 )}{{h}^{′}}$$

$${D}_{i , j}^{+ y} T = \frac{T ( i + 1 , j ) - T ( i , j )}{{h}^{′}}$$

$${D}_{i , j}^{- y} T = \frac{T ( i , j ) - T ( i - 1 , j )}{{h}^{′}}$$

The hash fast marching method is a method for simulation of surface evolution based on the principles of equations (1) and (2), and mainly may be into two steps: initialization and iterative front propagation.

FIG. 2 is a basic flowchart of a hash fast marching method, which specifically includes the following steps:

(1) According to specified simulation resolution requirements of the photolithography process (assuming that the simulation resolution is a μm), a substrate (including a photoresist and a substrate material) into a grid array consisting of small squares having a side length of a μm, a two-dimensional array is used to represent the grid array, a total photoresist etching (development) time is determined, and etching speeds of different photoresist and substrate material grid points are obtained according to physical and chemical models of the photolithography process to form a two-dimensional etching speed matrix ν (ν_{i,j} represents the etching speed of the grid point (i, j)). Because the substrate material does not react with the developer solution in the photoresist development process, the etching speed of the substrate material array unit is always 0.

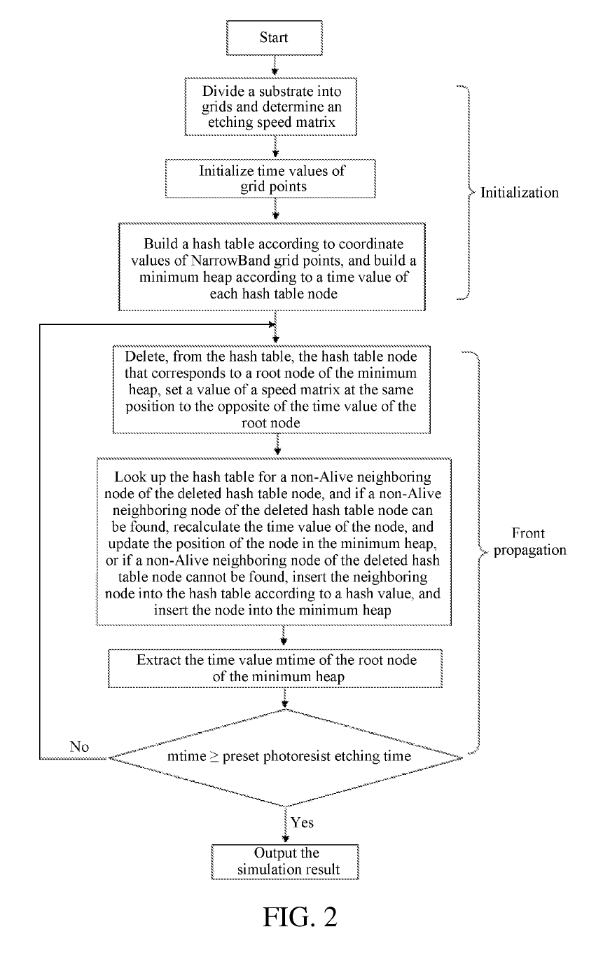

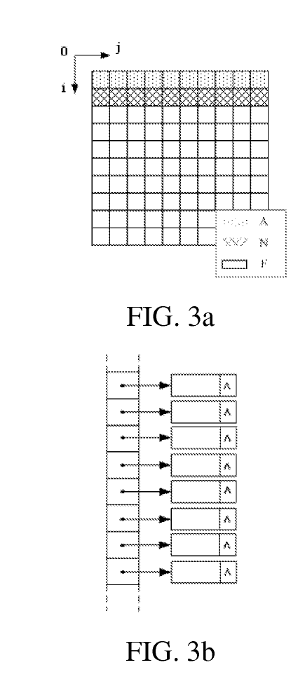

(2) Initialization of time values: In the grid point array of the fast marching method shown in FIG. 3, A represents Alive, that is, grid points inside the curve, N represents NarrowBand, that is, grid points on a boundary of the curve, and F represents FarAway, that is, grid points outside the curve. According to the size of the grid array obtained by dividing the substrate, Alive, NarrowBand, and FarAway arrays are built. A represents Alive, N represents NarrowBand, and F represents FarAway. Grid points with dotted patterns, that is, grid points when i=0, are stored in the Alive array, and represents grid points that have been crossed, where the initial time value is 0, and their time values will be frozen; grid points with meshed patterns, that is, grid points when i=1, are NarrowBand grid points, and represent neighboring grid points of Alive, that is, contour points of the curve, where their initial time values are assumed to be h′/ν(1,j); white grid points are stored as FarAway grid points, where their initial time values are assumed to be ∞.

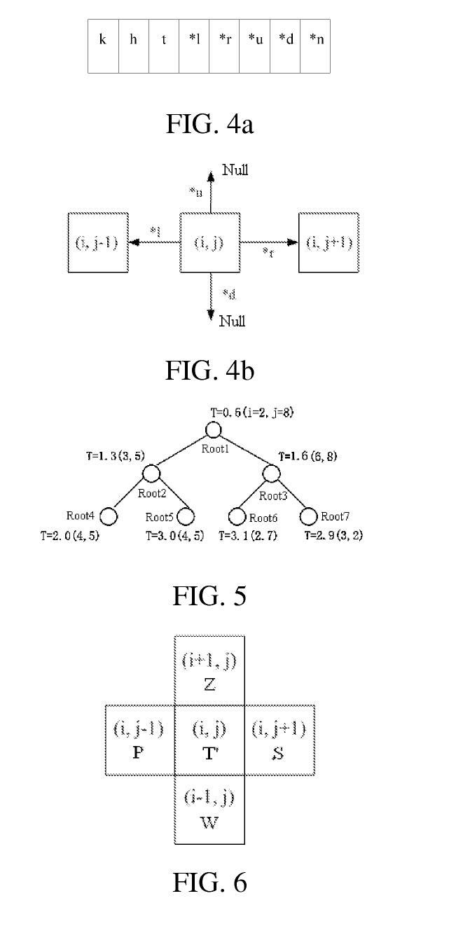

(3) Initialization of hash table and minimum heap: A hash table is built by using a modulo method. Assume that the hash function is H=index % P, where index represents a value in one dimension to which two-dimensional coordinates of a grid point is mapped, % represents the modulo operation, and P is the largest prime number less than the length of the hash table. Therefore, by means of the modulo operation, NarrowBand grid points in the two-dimensional grid are mapped to nodes in the hash table, as shown in FIG. 3a. In this way, a hash table is built according to hash values that are obtained by performing an operation on the coordinate values of the NarrowBand grid points, as shown in FIG. 3b, and the hash table node is used to store all necessary data information of the NarrowBand grid points. FIG. 4 is a view illustrating the data structure of NarrowBand hash table nodes. FIG. 4a illustrates a data format of hash table nodes, where each node includes coordinate values of the corresponding grid point, the position of the node in the minimum heap, the time value at which the curved surface reaches the node, four pointers for pointing to neighboring nodes in space, and a next pointer in the hash table that points to the next node; there is a total of eight pieces of data. k represents keynum and is used for storing coordinate values of the node, h represents heapnum and is used for storing the position of the node in the minimum heap, t represents time that refers to the time at which the curve reaches the node, *1, *r, *u, and *d* respectively represent *left, *right, *up, and *down pointers and are used for storing pointers that point to left, right, upper and lower neighboring nodes in space, and if a neighboring node already exists in the NarrowBand hash table, point to the node, or if a neighboring node does not exist, point to Null. By using a periodic boundary condition, values are assigned to keynum, time and the four neighboring node pointers of each hash table node, as well as the next pointer; however, a value needs to be assigned to heapnum in the NarrowBand hash table node after the minimum heap is built by using the time values of the NarrowBand grid points.

Because it often takes much time to directly look up for the minimum time value in the NarrowBand, a minimum heap is built to store time values of the NarrowBand in the hash fast marching method so as to increase the simulation speed.

Refer to FIG. 5. The minimum heap means that the time value of the root node (parent node at the highest level) is the minimum value among the time values of all nodes in the heap. The minimum heap is characterized in that the time value of a child node at each level is greater than the time value of a parent node, and the time values of two nodes at a same level are arbitrary. Therefore, the minimum value of the entire minimum heap appears at the root node. As shown in FIG. 5, the time value of a parent node Root1 is T=0.6 (the time value at which the grid point (2, 8) is reached), the time values of two child nodes Root2 and Root3 of the parent node Root1 are respectively T=1.3 (the time value at which the grid point (3, 5) is reached) and T=1.6 (the time value at which the grid point (6, 8) is reached). In this way, in the hash fast marching method, a minimum heap is built according to the result of initializing time values in the step (2), thus completing initialization of the minimum heap. After the time value of a node in the NarrowBand hash table is updated in the simulation process, the position of the node in the minimum heap also needs to be updated.

(4) Front propagation: The front propagation part of the hash fast marching method is an iterative process, and is mainly an operation performed on the NarrowBand hash table. In addition, insertion, deletion and internal re-sorting for the minimum heap are also involved. The insertion operation is mainly applied to the case where when a new node is added to the NarrowBand hash table, the node needs to be inserted into the minimum heap, and includes the following operational steps: first, inserting the time value time of the node into the last leaf node of the minimum heap, then comparing the time value of the node with that of the parent node, and if the time value of the node is greater than that of the parent node, ending the operation; or if the time value of the node is less than that of the parent node, interchanging the positions of the time value of the last leaf node and the time value of the parent node, continuing to compare the time value of the node with a parent node at a new position, and if the time value of the node is greater than that of the new parent node, ending the operation; or if the time value of the node is less than that of the new parent node, continuing to perform the comparison step; thus, the process is recursive for the parent nodes until the root node is reached. The complexity of the insertion operation is O(log(M)). The deletion operation is only used for looking up for the minimum time value; because the minimum value is at the root node, the current time is the minimum value of the root node, and the root node needs to be deleted after being extracted. A common method is to interchange the root node with the last node in the minimum heap, and then re-sort the new root node according to the properties of the minimum heap. Therefore, the time complexity for looking up for the minimum value is O(1) and the time complexity for re-sorting is O(log(M)).

The front propagation process of the hash fast marching method may be divided into the following two basic steps:

In a first step, the root node of the minimum heap is extracted, where the time value of the NarrowBand hash table node corresponding to the root node is the minimum time value (referred to as mtime) among the time values of all hash table nodes; the NarrowBand hash table node is deleted from the hash table, and is put into a queue for recycling deleted nodes; all pointers pointing to the node are set to Null, and a value of a speed array at the same position is set to the opposite of the minimum value, that is, set

ν(i,j)=mtime (3)

One reason of this step is that the time value of the Alive grid point is already fixed and do not need to be calculated again, therefore, the speed value of this grid point does not need to be reused, which is the basic premises of realizing reuse of the speed array. Another reason of this step is that the speed value of each grid point is sign-preserving, therefore the grid point opposite to the original sign of the array numerical can be considered to be the Alive grid point, and further the grid points in three states can be easily distinguished with reference to the NarrowBand hash table.

Therefore, the hash fast marching method realizes reuse of the speed array during propagation, which not only saves space, but also easily stores the time value and status of the Alive point without increasing the time complexity.

In a second step, the coordinate values of non-Alive neighboring nodes of the deleted hash table node and corresponding hash values are determined according to the geometric relationship of grid lattices. For each non-Alive neighboring node, a hash value obtained through calculation is looked up for in the NarrowBand hash table; if the hash value can be found, it indicates that the neighboring node is a node corresponding to the NarrowBand grid point, and its time value is recalculated, as shown in FIG. 6. Symbols in each node respectively represent the coordinate value and the time value, the node (i, j) to be updated is located in the center, and assuming that the time value of the node after being updated is T′, and the time values at which the four neighboring nodes are reached as respectively P, S, W, and Z, equation (2) may be changed to

$$\begin{matrix}{max ( max ( {T}^{′} - P , 0 ) , - min ( S - {T}^{′} , 0 ) )}^{2} \\ + {max ( max ( {T}^{′} - W , 0 ) , - min ( Z - {T}^{′} , 0 ) )}^{2}\end{matrix} = {h}^{′ 2} \text{/} {v}_{i , j}^{2} = {f}_{i , j}^{2} \qquad ( 4 )$$

In equation (4), for the purpose of brevity, set f_{i,j}=\sqrt{h′²/νi,j²}. Assuming A′=min (P, S, W, Z), it can be proved that the f_{i,j} value (f for short) for any grid point satisfies A′<T′<A′+f. The following can be obtained:

(a) When A′+f≦min(W,Z), equation (4) is simplified to (T′−A′)²=f²

(b) When A′+f>min(P, S), equation (4) is simplified to (T′−A′)²+(T′−min(W,Z))²=f²

In this way, the time value T′ corresponding to the node can be solved according to the relationship between the values of A′+f and min(W,Z), so as to complete updating of the time value of the NarrowBand neighboring node. To maintain the properties of the minimum heap, after the time value of the node is updated, the position of the related node in the minimum heap needs to be re-sorted, and then the heapnum value of the node in the hash table is updated. If the hash value of the neighboring node cannot be found in the NarrowBand hash table, it indicates that the neighboring node does not exist in the NarrowBand hash table, and accordingly, the neighboring node undoubtedly corresponds to the FarAway grid point, that is, the node (and corresponding grid point) is not a NarrowBand hash table node in the current simulation step, but will become a NarrowBand hash table node in the next simulation step. The time value and the hash value of the neighboring node are calculated according to the above method, the node is inserted into the NarrowBand hash table according to the hash value, the neighboring node is inserted into the minimum heap according to the time value, and a value is assigned to heapnum of the corresponding hash table node.

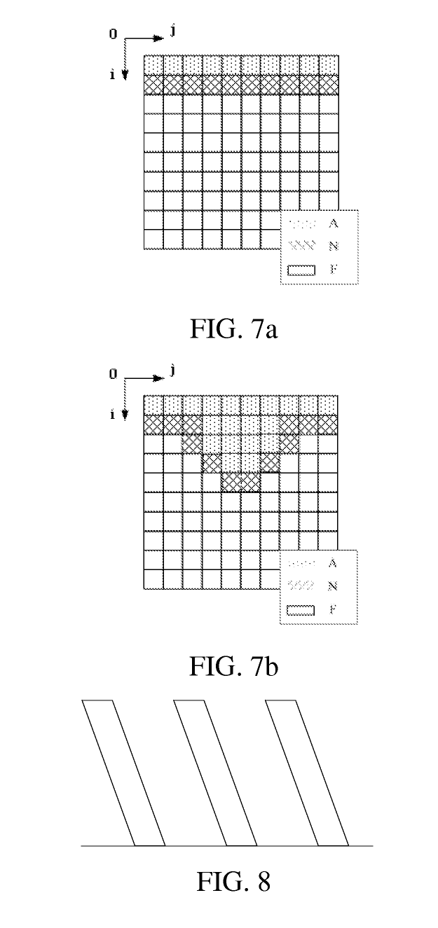

As can be known from the above process, the process of surface evolution in the photoresist etching process can be simulated by performing an operation on the NarrowBand hash table and performing insertion, deletion and internal sorting operations for the minimum heap, and as shown in FIG. 7, the etching surface continuously evolves as the etching time increases.

(5) The front propagation step (4) is repeated, until the time value of the point min reaches a preset photoresist etching time (development time); at this time, a curve consisting of NarrowBand grid points, that is, a surface profile of the photoresist in the preset etching time, can be obtained according to the coordinate values of the NarrowBand grid points that are stored in the NarrowBand hash table node.

A 140 μm thick SU-8 resist oblique incidence photolithography process is successfully simulated on a Core2/2 GHz computer. The simulation result is shown in FIG. 8, where the photoresist has a line width of 30 μm and a line spacing of 60 μm, and the photoresist etching time is 600 s. The obtained simulation result is consistent with the experimental result. For an M×M grid array, the hash fast marching simulation method requires a memory space of 4.8M²+32O(M) bytes; while the conventional fast marching simulation method requires a memory space of 3×4M²+0.1×4M²=12.4M² bytes. Therefore, when M takes a large value, the present invention saves a storage space of (12.4M²-4.8M²-32O(M))/12.4M²=61.3% compared to the conventional fast marching simulation method. Compared to the improved fast marching method previously proposed by the inventor, the present invention can further reduce the required memory space by about 30%, and increase the speed by about 12%, which is of practical significance to achieve high precision simulation of the thick resist photolithography process.

What is claimed is:

1. A hash fast marching method for simulation of surface evolution in a photoresist etching process, comprising the following steps:
step 1: dividing a substrate into a grid array consisting of small squares, using a two-dimensional array to represent the grid array, determining a total photoresist etching time, calculating etching speeds of different photoresist and substrate material grid points, and obtaining a two-dimensional etching speed matrix;
step 2: defining grid points on a boundary of a curve as NarrowBand, grid points inside the curve as Alive, and grid points outside the curve as FarAway, and initializing time values of all the grid points according to the etching speeds of the different grid points;
step 3: building a NarrowBand hash table according to coordinate values of the NarrowBand grid points by using a periodic boundary condition, building a minimum heap according to a time value of each hash table node, and assigning values to keynum, time, and heapnum of each hash table node, four neighboring node pointers, and a next pointer;
step 4: extracting a top root node from the minimum heap, deleting the node from the NarrowBand hash table, putting the node into a recycling queue, setting all pointers that point to the node to Null, and setting a value of a speed array at the same position to the opposite of the minimum value; looking up the NarrowBand hash table for a non-Alive neighboring node of the node with the minimum time value, and if a non-Alive neighboring node of the node with the minimum time value can be found, recalculating the time value of the node, and updating the position of the node in the minimum heap, or if a non-Alive neighboring node of the node with the minimum time value cannot be found, inserting the neighboring node into the NarrowBand hash table according to a hash value; and at the same time inserting the node into the minimum heap according to the time value that is calculated first time, comprising completing internal re-sorting of the minimum heap; and
step 5: repeating the step 4 until the time value reaches a preset photoresist etching time, and at this time, obtaining a curve consisting of NarrowBand grid points, that is, a surface profile of the photoresist in the preset etching time, according to the coordinate values of the NarrowBand grid points that are stored the hash table nodes.

2. The hash fast marching method for simulation of surface evolution in a photoresist etching process according to claim 1, wherein the time value of a child node at each level of the minimum heap is greater than the time value of a parent node, and the time values of two nodes at a same level are arbitrary.
